(19) United States
(12) Patent Application Publication
(10) Pub. No.: US 2026/0164623 A1
(43) Pub. Date: Jun. 11, 2026

(54) ADAPTIVE COOLING TRAY FOR UNDER HOOD AUTOMOTIVE COMPONENTS

(71) Applicant: FCA US LLC, Auburn Hills, MI (US)

(72) Inventors: Arturo Guzman-Magana, Auburn Hills, MI (US); Venkata Krishna Mohan Chagarlamudi, Auburn Hills, MI (US)

(21) Appl. No.: 18/976,860

(22) Filed: Dec. 11, 2024

(51) Int. Cl. H05K 7/20; B60R 16/023

(52) U.S. Cl. CPC H05K 7/20863; B60R 16/0238; H05K 7/20145

(57) ABSTRACT

An electrical component housing has a box shaped receptacle having at least one wall. A plurality of apertures are in the at least one wall. A plate covers the apertures. The plate includes a plurality of apertures. The plate is movable with respect to the walls to open and block desired apertures in the at least one wall. An inlet enables ram air to enter into the housing through the apertures in the plate and wall to cool the electrical components in the housing.

### FIELD

The present disclosure relates to automobiles and, more particularly, to electrical components.

### BACKGROUND

This section provides background information related to the present disclosure which is not necessarily prior art.

A common warranty issue in the automotive industry is related to electronic component life. The electronic components are exposed to heat cycles. The heat cycles deteriorate the life span of electrical performance. Also, the heat cycles reduce performance, dry out the electronic effect the recharging capability or damage the internal electronics. Accordingly, depending upon the heat generated, the deterioration of the life span is increased by overheating at high temperatures. The overheating and high temperatures makes it possible for some of the components to become unsoldered. This leads to damage of the electronic chips or overcharging of the system.

While it would be conducive to remove the component from under the hood around the engine, it is not feasible. The electric components could be positioned in the rear truck of a vehicle; however, at this point, they would not have direct access to ram air cooling. The ram air cooling would need to be funneled into the trunk. Also, moving of the electronical components to other locations away from the engine compartment will change the weight balance of the vehicle.

Additionally, the electrical components would require long wiring harnesses from the front to the rear of the vehicle. Additionally, moving the electrical components into the under hood area for ram air cooling causes overcrowding and change in weight distribution. A package is now needed with long wiring either inside or under the vehicle. There is also concern of having some of these components in the trunk as they can move under an impact situation. There is always a need to provide designers with the freedom to effectively use the space in the under hood and under body areas due to functionality.

Accordingly, the present disclosure enables the electronics to be positioned under the hood. The present disclosure solves the packaging issue of where to put electrical components sensitive to heat to avoid thermal exposure. The present disclosure provides for the electronical components to be cooled by a ram air system. Thus, the present system enables proper weight balancing of the vehicle and eliminates long wiring from the front to the rear of the vehicle. Also, the present disclosure enables utilization of ram air to cool the components without changing the weight distribution.

### SUMMARY

This section provides a general summary of the disclosure, and is not a comprehensive disclosure of its full scope or all of its features.

According to a first aspect of the disclosure, an electrical component housing comprises a box shaped receptacle having at least one wall. A plurality of apertures are in the at least one wall. A plate to cover the apertures is adjacent the wall. The plate includes a plurality of apertures. The plate is movable with respect to the wall to open and block desired apertures in the at least one wall. An inlet enables ram air to enter into the housing through the apertures in the plate and wall to cool the electrical components in the housing. A channel is formed in the housing and is coupled with the inlet. The channel is adjacent the plate. The plate moves to open desired apertures to provide a grid for ram air distribution into the housing. The plate enables directing of the ram air to desired positions in the housing. Additionally, a fan for actively forcing air into the housing could be incorporated. A plenum is adjacent the housing to receive the ram air. The plenum surrounds the at least one wall. Additionally, the plenum surrounds the housing. The plate slides on the at least one wall.

According to a second aspect of the disclosure, a vehicle comprises an engine compartment, an electrical component in the engine compartment and an electrical component housing. The electrical component housing comprises a box shaped receptacle having at least one wall. A plurality of apertures are in the at least one wall. A plate to cover the apertures is adjacent the wall. The plate includes a plurality of apertures. The plate is movable with respect to the wall to open and block desired apertures in the at least one wall. An inlet enables ram air to enter into the housing through the apertures in the plate and wall to cool the electrical components in the housing. A channel is formed in the housing and is coupled with the inlet. The channel is adjacent the plate. The plate moves to open desired apertures to provide a grid for ram air distribution into the housing. The plate enables directing of the ram air to desired positions in the housing. Additionally, a fan for actively forcing air into the housing could be incorporated. A plenum is adjacent the housing to receive the ram air. The plenum surrounds the at least one wall. Additionally, the plenum surrounds the housing. The plate slides on the at least one wall.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a perspective schematic view of a vehicle with the present disclosure.

FIG. 2 is a perspective side elevation view of an electrical component housing.

FIG. 3 is an exploded perspective view of the housing.

FIG. 4 is a schematic view of a fully opening of the grid.

FIG. 5 is a schematic view of a partial opening grid.

FIG. 6 is another embodiment of the present disclosure.

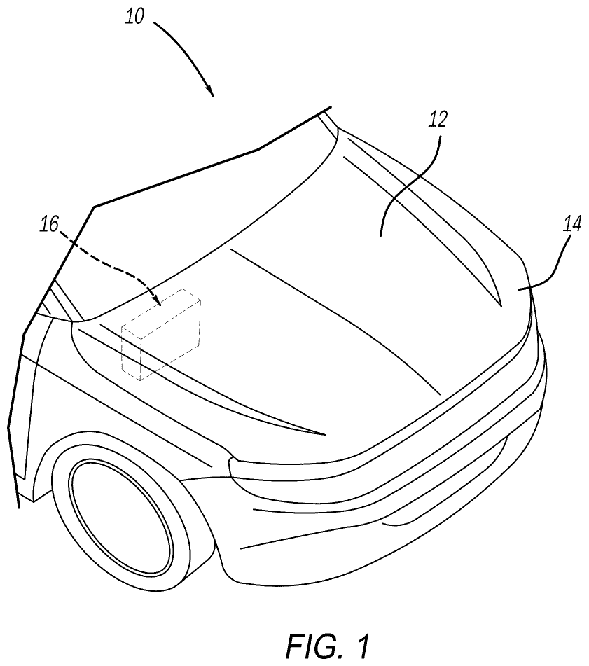

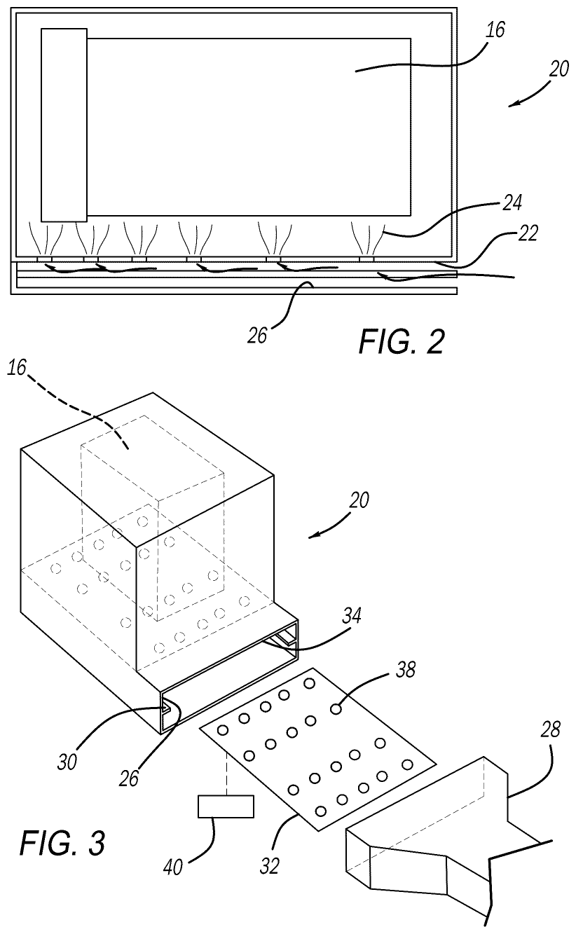

Corresponding reference numerals indicate corresponding parts throughout the several views of the drawings.

### DETAILED DESCRIPTION

Example embodiments will now be described more fully with reference to the accompanying drawings.

Turning to the figures, a vehicle is illustrated and designated with the reference numeral 10. The vehicle includes a hood 12 covering an engine compartment 14. The engine compartment 14 includes electronics 16. The electronics 16 include an electronic component housing 20.

The electronic component housing 20 has an overall box shape for housing the electrical component 16. The housing 20 includes at least one wall 22. The wall 22 may be positioned with respect to the housing at a bottom, top, side or the like wall. The wall 22 includes a plurality of apertures 24. The apertures 24 can vary in size from larger to smaller as desired to enable air to enter into the housing to cool the electrical components 16.

A channel 26 is formed adjacent to the wall 22. The channel 26 enables the ram air to enter into the housing 20. An inlet pipe or passage 28 is coupled with the channel 26 to enable the ram air flow to enter into the housing 20. Optionally, the passage 28 can have a fan 31.

The channel 20 includes a shelf 30 to receive a plate 32. The shelf 30 includes a pair of flanges 34, one on each side of the channel 26 and adjacent to the wall 22. The flanges 34 generally extend the length of the channel to enable the plate 32 to be positioned on the flanges 34 on the shelf 30.

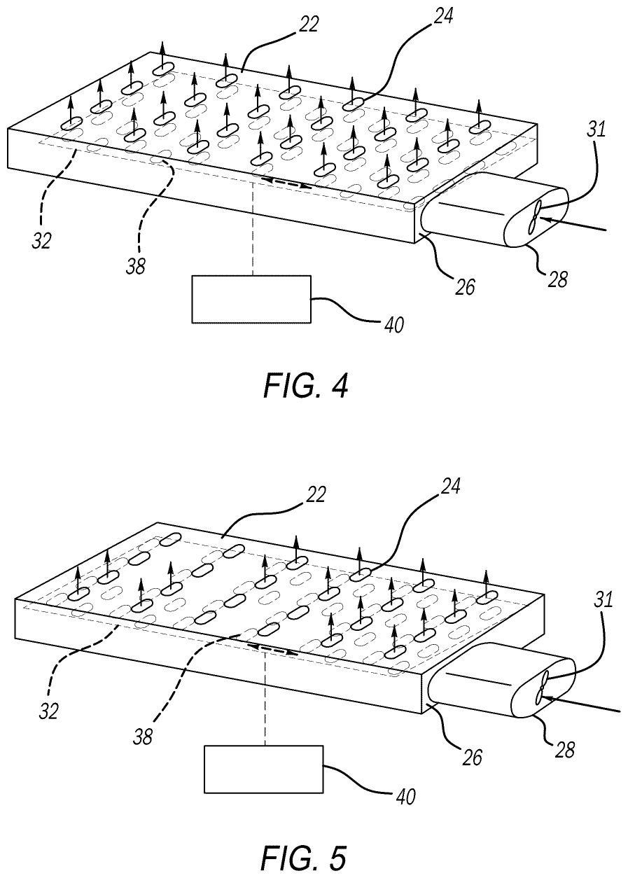

The plate 32 includes a plurality of apertures 38 that may vary in size and pattern. In one embodiment, the apertures 38 align with wall apertures 24 as illustrated in FIG. 4. Thus, a full grid opening occurs and all the apertures 24 in the wall 22 are open to enable air to enter into the housing to cool the electrical components 16. Also, the plate 32 can be moved on the shelf so that a partial grid, as illustrated in FIG. 5, can be open to enable the air to be directed to specific spots of the electrical components 16. A controller 40 moves the plate between positions.

Thus, the ram air enters from the inlet 28 into the channel 26 at the housing 20. The channel 26 can be an extension of the housing walls to form the channel 26. The air enters the channel 26 and then is directed toward the aperture 38 and the plate 32. Depending upon the alignment of the plate apertures 38 with the wall apertures 24, the air will enter into the housing 20 to cool the electrical components 16 at a desired space. Also, the channel 26 acts as a plenum to receive the air and distribute it into the apertures 38, 24.

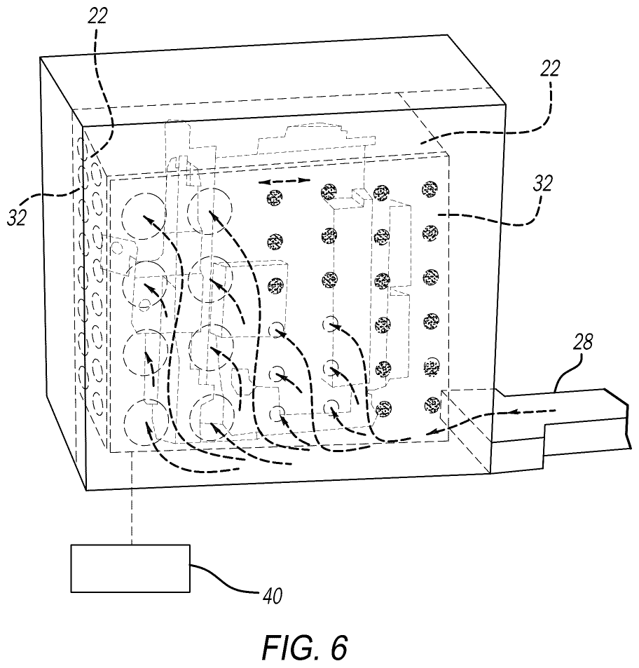

Turning to FIG. 6, a second embodiment is illustrated. Here, the channel or plenum surrounds all the walls 22. Here, the housing is a box within a box enabling the air to enter into the plenum and then be directed to a desired side of the electrical components 16. Accordingly, a plurality of plates may be positioned in the plenum so that the desired plate apertures contact the desired wall apertures so that the air flow can be directed to the desired position of the electrical components. In the present case, due to the cuboidal shape of the housing 20, the inner box could include as many as six walls while there could be as many as six plates, one adjacent each wall, to enable the air to be directed to the electrical components. Thus, multiple walls with multiple plates can be used to direct the air at the electrical components.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. An electrical component housing comprising:
a box shaped receptacle having at least one wall;
a plurality of apertures are in the at least one wall;
a plate for covering the apertures, the plate including a plurality of apertures, the plate being movable with respect to the at least one wall to open and block desired apertures in the at least one wall; and
an inlet for enabling ram air to enter into the housing through the apertures in the plate and at least one wall for cooling the electrical components in the housing.

2. The electrical component housing of claim 1, wherein a channel is formed in the housing, the channel coupled with the inlet.

3. The electrical component housing of claim 1, wherein the channel is adjacent the plate.

4. The electrical component housing of claim 1, wherein the plate moves to open desired apertures to provide a grid for the ram air distribution into the housing.

5. The electrical component housing of claim 1, wherein the plate enables directing of the ram air to desired positions in the housing.

6. The electrical component housing of claim 1, further comprising a fan for actively forcing air into the housing.

7. The electrical component housing of claim 1, wherein a plenum is adjacent the housing for receiving the ram air.

8. The electrical component housing of claim 7, wherein the plenum surrounds the at least one wall.

9. The electrical component housing of claim 7, wherein the plenum surrounds the housing.

10. The electrical component housing of claim 1, wherein the plate slides on the at least one wall.

11. A vehicle comprising:
an engine compartment;
an electrical component in the engine compartment;
a box shaped receptacle having at least one wall;
a plurality of apertures are in the at least one wall;
a plate for covering the apertures, the plate including a plurality of apertures, the plate being movable with respect to the at least one wall to open and block desired apertures in the at least one wall; and
an inlet for enabling ram air to enter into the housing through the apertures in the plate and at least one wall for cooling the electrical components in the housing.

12. The vehicle of claim 11, wherein a channel is formed in the housing, the channel coupled with the inlet.

13. The vehicle of claim 11, wherein the channel is adjacent the plate.

14. The vehicle of claim 11, wherein the plate moves to open desired apertures to provide a grid for the ram air distribution into the housing.

15. The vehicle of claim 11, wherein the plate enables directing of the ram air to desired positions in the housing.

16. The vehicle of claim 11, further comprising a fan for actively forcing air into the housing.

17. The vehicle of claim 11, wherein a plenum is adjacent the housing for receiving the ram air.

18. The vehicle of claim 17, wherein the plenum surrounds the at least one wall.

19. The vehicle of claim 17, wherein the plenum surrounds the housing.

20. The vehicle of claim 11, wherein the plate slides on the at least one wall.
